(19) United States
(12) Patent Application Publication
(10) Pub. No.: US 2013/0045374 A1
(43) Pub. Date: Feb. 21, 2013

(54) NANO-LAMINATED FILM WITH TRANSPARENT CONDUCTIVE PROPERTY AND WATER-VAPOR RESISTANCE FUNCTION AND METHOD THEREOF

(71) Applicants: CHIH-CHIEH YU, Taichung City (TW); MENG-YEN TSAI, Nantou (TW); CHI-CHUNG KEI, Pingtung (TW); BO-HENG LIU, Taipei (TW); CHIEN-NAN HSIAO, Taichung City (TW)

(72) Inventors: CHIH-CHIEH YU, Taichung City (TW); MENG-YEN TSAI, Nantou (TW); CHI-CHUNG KEI, Pingtung (TW); BO-HENG LIU, Taipei (TW); CHIEN-NAN HSIAO, Taichung City (TW)

(73) Assignee: NATIONAL APPLIED RESEARCH LABORATORIES, Taipei (TW)

(21) Appl. No.: 13/458,458

(22) Filed: Apr. 27, 2012

(30) Foreign Application Priority Data
Aug. 17, 2011 (TW) 100129471

(51) Int. Cl. B32B 9/04; B05D 5/12

(52) U.S. Cl. 428/220; 428/469; 428/472; 428/332; 427/126.3; 427/126.5; 427/126.4

(57) ABSTRACT

The present invention discloses a nano-laminated film with transparent conductive property and water-vapor resistance function and method thereof. The nano-laminated film comprises a plurality of first metal oxide layers and a plurality of second metal oxide layers. Wherein, the first metal layers and the second metal layers are made of different materials, and there is a spinel phase formed between the first metal layers and the second metal layers.

### CROSS-REFERENCE TO RELATED APPLICATION

This application claims the benefit of Taiwan Patent Application No. 100129471, filed on Aug. 17, 2011, in the Taiwan Intellectual Property Office, the disclosure of which is incorporated herein in its entirety by reference.

### BACKGROUND OF THE INVENTION

1. Field of the Invention

The present invention relates to a nano-laminated film and a manufacturing method thereof, and more particularly to the nano-laminated film with transparent conductive property and water-vapor resistance function applied in electronic products and the method thereof.

2. Description of Related Art

In recent years, optoelectronic products including organic light emitting diode (OLED) devices, organic photovoltaic (OPV) batteries, thin film photovoltaic batteries, flexible LCD, and the electronic paper bloom, thus playing a decisive role in present and future markets. However, these electronic devices particularly OLED and OPV devices may be damaged easily when they come in contact with water vapor and oxygen in the air, and the permeability of water vapor and oxygen must be maintained at a level below 10⁻⁶ g/m²/day and 10⁻⁵ cm³/m²/day respectively to prevent the devices from being damaged by water vapor and oxygen. Therefore, it is an important and urgent subject for related manufacturers to develop a packaging technology adopting water vapor resistive films to meet user requirements and protect high-end electronic devices from being interfered by water vapor and oxygen.

The conventional packaging technology of electronic devices mainly includes a glass packaging method and a thin film packaging method, wherein the glass packaging method is the only packaging method capable of meeting the requirement of resisting water vapor in OLED devices at present, of the glass packaging process, only an upper and lower glass plates are used to package and glue a device in between, so that the glass packaging method has the advantages of a simple manufacturing process and a low cost. However, the conventional glass packaging method is restricted by the properties of glass, and the glass packaging method cannot be applied to manufacturing flexible electronic devices. Almost all of the future electronic devices will have the ability to be bent flexibly or designed with a light and thin design, and thus the thin film packaging technology becomes a main target of the future development.

The thin film packaging technology can be divided into inorganic thin film, organic thin film and composite inorganic/organic thin film packaging technologies. At present, if the inorganic thin film is used as the packaging thin film of the electronic devices, water vapor transmission path may be formed easily in an inorganic thin film manufacturing by the conventional manufacturing process, thus resulting in a high defective rate and a low density of the thin film. In addition, the growing mechanism of the thin film manufactured by the conventional manufacturing process includes the steps of first growing and nucleating island structure on a substrate to form the thin film, and then a crystal boundary is formed in the thin film. These defects cause the flexible electronic devices are bent, small cracks are easily formed or forming a water vapor transmission path to disable the electronic device. Therefore, the thin film requires a relatively larger thickness, and the present existing inorganic thin film packaging technologies still fail to meet the requirements of industrial applications and are limited by the high level of difficulty of manufacturing the high-performance thin film by the conventional manufacturing process, so that the area of the OLED products cannot be increased, and the high cost cannot be lowered.

Although the organic materials and composite materials used in present existing packaging technologies can meet the water vapor resisting performance requirement for industrial applications, yet the organic materials usually have a short life and indirectly affect the service life of the devices. To avoid defects and ineffective packages, organic materials and composite materials are used for the packaging, but the thickness of the package is larger and the surface flatness and roughness are lower, so that the optoelectronic properties of the devices may be attenuated easily.

Similarly, if a multi-layered inorganic/organic thin film is used for manufacturing a water vapor resisting layer, both reliability and service life of the organic thin film are poor and fail to enhance the service life of the OLED products. In addition, if chemical solutions are used for preparing the multi-layered inorganic and organic thin film to produce large-area products, the volatile solvent may cause defects of the thin film structure and the problem of a high porosity of the thin film, such that the large-area OLED products cannot be manufactured.

In view of the aforementioned shortcomings of the conventional thin film packaging technologies and that almost all future electronic devices will be flexible, thin, and light, developing a thin film with good water vapor resistance and flexibility to package various electronic products with different areas and sizes demands immediate attention and feasible solutions.

### SUMMARY OF THE INVENTION

In view of the aforementioned problems of the prior art, it is a primary objective of the present invention to provide a nano-laminated film with transparent conductive property and water-vapor resistance function and a manufacturing method thereof to overcome the problems including the water vapor blocking effect and the short service life of the conventional nano-laminated film that is applied for packaging an electronic product.

To achieve the foregoing objective, the present invention provides a nano-laminated film with transparent conductive property and water-vapor resistance function comprising a plurality of nanocomposite layers, disposed on a substrate, and each of the nanocomposite layers further comprises a plurality of first metal oxide layers and a plurality of second metal oxide layers formed on the first metal oxide layers, wherein, the first metal oxide layers and the second metal oxide layers are formed by different materials, and a spinel phase is formed at a contact interface of the first metal oxide layers and the second metal oxide layers.

Preferably, the first metal oxide layer is a zinc oxide layer, a titanium aluminum oxide layer, an aluminum oxide layer, an indium oxide layer, a titanium oxide layer, a manganese oxide layer, a germanium oxide layer or a germanium indium oxide layer.

Preferably, the second metal oxide layer is a zinc oxide layer, a titanium aluminum oxide layer, an aluminum oxide layer, an indium oxide layer, a titanium oxide layer, a manganese oxide layer, a germanium oxide layer or a germanium indium oxide layer.

Preferably, if the first metal oxide layer or the second metal oxide layer is a zinc oxide layer, the zinc oxide layer has a thickness falling within a range from 1.7 Å to 2 Å.

Preferably, if the first metal oxide layer or the second metal oxide layer is an aluminum oxide layer, the aluminum oxide layer has a thickness falling within a range from 0.91 to 1.11.

Preferably, each of the nanocomposite layers has a plurality of aluminum oxide layers and a plurality of zinc oxide layers in a ratio of 2:98 to 5:95.

Preferably, the plurality of nanocomposite layers has a total thickness, and if the total thickness is greater than 80 nm, the plurality of nanocomposite layers has a resistivity falling within a range from 10⁻³ to 10⁻⁴ a-cm, and a water vapor transmission rate below 0.001 g/m²day.

Preferably, the spinel phase has an average density falling within a range from 5.5 g/cm³ to 7.2 g/cm³.

Preferably, the substrate is a plastic substrate.

Preferably, the plurality of nanocomposite layers serves as an upper electrode or a lower electrode of an organic light emitting diode (OLED).

To achieve the aforementioned objective, the present invention further provides a manufacturing method of a nano-laminated film with transparent conductive property and water-vapor resistance function, using an atomic deposition method for the manufacture, and comprising the steps of: repeating a supercycle step to form a plurality of nanocomposite layers on a substrate, and the supercycle step comprising: repeating a first unit cycle step to form a plurality of first metal oxide layers; and repeating a second unit cycle step to form a plurality of second metal oxide layers; wherein the first metal oxide layers and the second metal oxide layers are made of different materials, and the first unit cycle step and the second unit cycle step are performed in a reaction chamber, and a reaction pressure of the reaction chamber, a reaction temperature of the substrate, a percentage of numbers of the first metal oxide layers and the second metal oxide layers of each nanocomposite layer are controlled, and a spinel phase is formed at a contact interface of the first metal oxide layer and the second metal oxide layer.

Preferably, the first metal oxide layer is a zinc oxide layer, a titanium aluminum oxide layer, an aluminum oxide layer, an indium oxide layer, a titanium oxide layer, a manganese oxide layer, a germanium oxide layer or a germanium indium oxide layer.

Preferably, the second metal oxide layer is a zinc oxide layer, a titanium aluminum oxide layer, an aluminum oxide layer, an indium oxide layer, a titanium oxide layer, a manganese oxide layer, a germanium oxide layer or a germanium indium oxide layer.

Preferably, if the first metal oxide layer or the second metal oxide layer is a zinc oxide layer, the zinc oxide layer has a thickness falling within a range from 1.7 Å to 2 Å.

Preferably, if the first metal oxide layer or the second metal oxide layer is an aluminum oxide layer, the aluminum oxide layer has a thickness falling within a range from 0.91 to 1.11.

Preferably, the reaction pressure falls within a range from 2 Torrs to 14 Torrs, and the temperature of the substrate falls within a range from 100° C. to 250° C.

Preferably, the number of aluminum oxide layers and the number of zinc oxide layers in each of the nanocomposite layers are in a ratio falling within a range from 2:98 to 5:95.

The plurality of nanocomposite layers has a total thickness, and if the total thickness is greater than 80 nm, the plurality of nanocomposite layers has a resistivity falling within a range from 10⁻³Ω-cm to 10⁻⁴ Ω-cm, and the water vapor transmission rate is below 0.001 g/m²day.

Preferably, the substrate is a plastic substrate.

Preferably, the plurality of nanocomposite layers serves as an upper electrode or a lower electrode of an organic light emitting diode (OLED).

In summation, the nano-laminated film of the present invention has the following advantages:

(1) The atomic layer deposition (ALD) technology is used to manufacture the nano-laminated film of the present invention, and the temperature and pressure of the manufacturing process and the composition of the thin film are controlled and adjusted to produce a nano-laminated film having a high-density spinel phase interface layer with different numbers of layers, thickness and density in a thin film manufacturing process to achieve an efficient water vapor blocking effect and a water vapor transmission rate below 0.001 g/m²day.

(2) The atomic layer deposition (ALD) technology is used to manufacture the nano-laminated film of the present invention that can meet the industrial standard of the electric conduction of electronic devices with a low resistivity from 10⁻³ Ω-cm to 10⁻⁴ Ω-cm.

(3) The atomic layer deposition (ALD) technology is used to manufacture the nano-laminated film of the present invention to produce products with less defects and better water vapor transmission rate (below 0.001 g/m²day) than those produced by the conventional methods. Since a thin film with even thickness can be formed by the present invention, therefore the required thickness is smaller than that required in the conventional manufacturing process, so that when the invention is applied to package flexible electronic devices, a thinner thin film may not be cracked easily by the bending of the flexible electronic device and the service life of the electronic device can be extended.

(4) The atomic layer deposition (ALD) technology is used to manufacture the nano-laminated film of the present invention to overcome the problems of producing large-area packaging thin film in a conventional manufacturing process, so as achieve a low defective rate in the production of the large-area thin film with a low defective rate and a high performance.

### BRIEF DESCRIPTION OF THE DRAWINGS

FIG. 1 is a schematic view of a nano-laminated film in accordance with a preferred embodiment of the present invention;

FIG. 2 is a schematic view of a supercycle step of a manufacturing method of a nano-laminated film of the present invention;

FIG. 3 is a schematic view of a first unit cycle step of a manufacturing method of a nano-laminated film of the present invention;

FIG. 4 is a schematic view of a second unit cycle step of a manufacturing method of a nano-laminated film of the present invention;

FIG. 5 is a graph of surface roughness of a nanocomposite layer versus percentage of number of aluminum oxide (Al₂O₃) layers in accordance with the present invention;

FIG. 6 is a graph of surface roughness of a nanocomposite layer of a nano-laminated film versus substrate reaction temperature in accordance with the present invention;

FIG. 7 is a schematic view of a nano-laminated film in accordance with a first preferred embodiment of the present invention;

FIG. 8 is a transmission electronic microscope (TEM) photo of a nano-laminated film in accordance with the first preferred embodiment of the present invention;

FIG. 9 is a graph of water vapor blocking effect versus percentage of numbers of aluminum oxide layers (0% to 5%) of a nano-laminated film in accordance with the first preferred embodiment of the present invention;

FIG. 10 is a schematic view of a nano-laminated film in accordance with a second preferred embodiment of the present invention; and

FIG. 11 is a schematic view of a nano-laminated film applied for packaging an OLED in accordance with the present invention.

### DETAILED DESCRIPTION OF THE PREFERRED EMBODIMENTS

The foregoing and other objectives, technical characteristics and advantages of the present invention will become apparent with the detailed description of preferred embodiments accompanied with related drawings as follows.

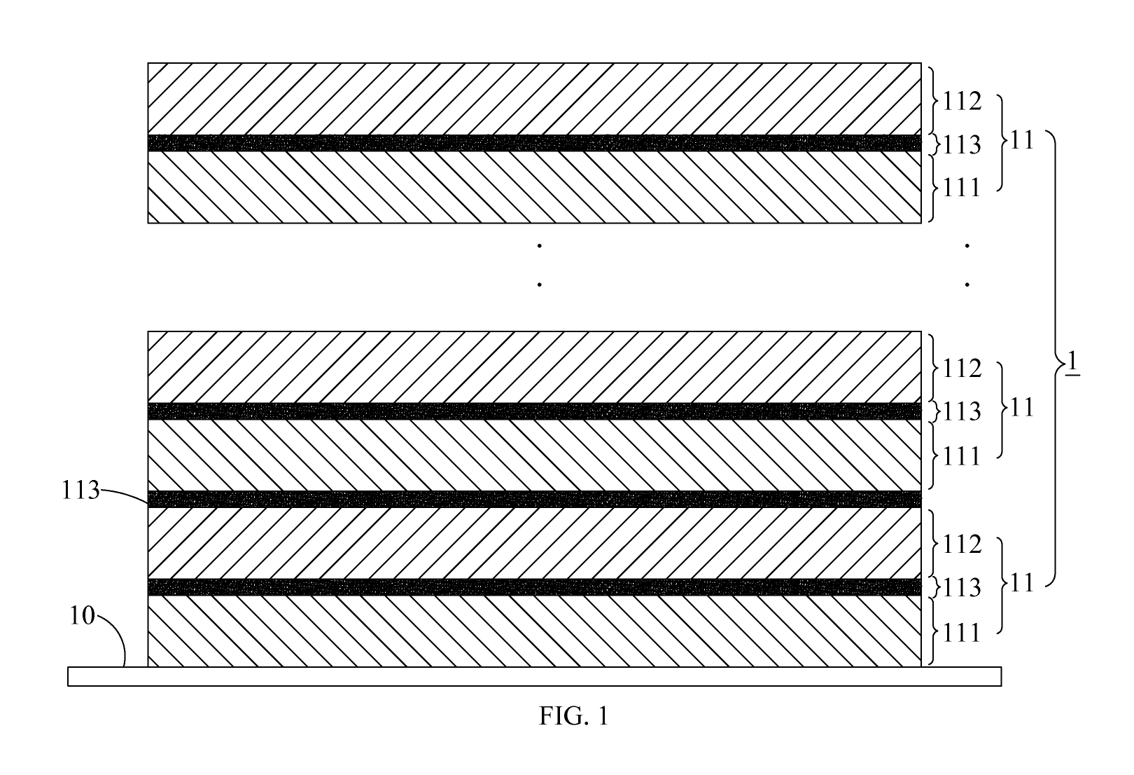

With reference to FIG. 1 for a schematic view of a nano-laminated film in accordance with a preferred embodiment of the present invention, the nano-laminated film 1 is formed on a surface of a substrate 10 of a package device, and a nanocomposite layer 11 is laminated repeatedly to achieve the packaging effect. Each nanocomposite layer 11 is comprised of a plurality of first metal oxide layers 111 and a plurality of second metal oxide layers 112, and the plurality of second metal oxide layers 112 is formed on the plurality of first metal oxide layers 111 respectively.

Wherein, a contact interface is formed between the plurality of first metal oxide layers 111 and the plurality of second metal oxide layers 112 in the structure of each nanocomposite layer 11, and a first metal oxide and a second metal oxide are contacted with each other to form a spinel phase 113. Similarly, two laminated nanocomposite layers are formed on the substrate 1 by laminating a plurality of first metal oxide layers 111 of a nanocomposite layer onto a second metal oxide layer 112 of another nano metal layer, so that a spinel phase 113 is also formed between two laminated nanocomposite layers.

The structure of the nano-laminated film 1 as shown in FIG. 1 can further comprise a plurality of layers coated onto the uppermost nanocomposite layer and formed by covering the second metal oxide onto the uppermost nanocomposite layer.

In the structure of the nano-laminated film 1 of the present invention, the first metal oxide layer 111 and the second metal oxide layer 112 are made of different materials. The first metal oxide layer 111 is a transparent conductive metal oxide layer which can be a zinc oxide (ZnO) layer, an aluminum oxide (Al₂O₃) layer, an indium oxide layer, a titanium oxide layer, a manganese oxide layer, a germanium oxide layer or a germanium indium oxide layer, and the second metal oxide layer 112 can also be a transparent metal oxide layer which can be a zinc oxide layer, an aluminum oxide (Al₂O₃) layer, an indium oxide layer, a titanium oxide layer, a manganese oxide layer, a germanium oxide layer or a germanium indium oxide layer. The substrate 10 can be a plastic substrate serving as a portion of an electronic device including polyethylene-2,6-naphthalate (PEN), polymethylmethacrylate (PMMA), or the uppermost surface of the electronic device. In addition, the nano-laminated film of the present invention whose thickness is controlled to achieve a resistivity ranging from 10⁻³Ω-cm to 10⁻⁴ Ω-cm to provide good conductivity, so that it can serve as an upper electrode or a lower electrode of an organic light emitting diode (OLED) in an application of packaging the OLED.

The nano-laminated film 1 of the present invention is mainly manufactured by the atomic layer deposition (ALD) technology, and the deposition conditions of the first metal oxide layer 111 and the second metal oxide layer 112 are controlled in the manufacturing process to optimize the roughness, density and thickness of the thin film and form a high-density spinel phase 113 between different metal oxide layers, and the spinel phase comes with a density from 4 g/cm³ to 7 g/cm³ depending on the types of first metal oxide layers 111 and second metal oxide layers 112. Compared with the conventional nano-laminated film, the present invention adopts the atomic layer deposition (ALD) technology to optimize the surface roughness and the density in each layer of the nano-laminated film and form the spinel phase easily. Therefore, a plurality of nanocomposite layers is laminated, and the nano-laminated film of the present invention can be manufactured with a lower defective rate and a less number of water vapor transmission path to achieve an efficient water vapor resisting effect. In addition, the atomic layer deposition (ALD) technology uses a chemical adsorption reaction process to form the thin film structure, so that a thin film with a thickness that is more even than the conventional thin film can be formed to reduce the total thickness of the thin film and facilitate its application for packaging flexible electronic devices.

In the manufacturing method of the nano-laminated film of the present invention, a supercycle step is performed at the substrate 10 to form a first nanocomposite layer 11, and supercycle step is repeated for several times to form a plurality of nanocomposite layers 11 on the substrate 10.

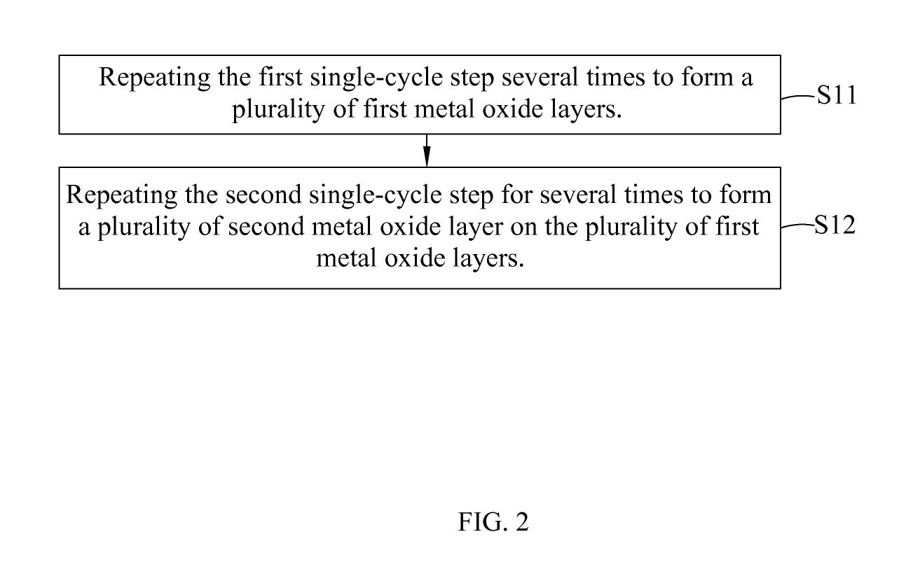

With reference to FIG. 2 for a schematic view of a supercycle step of a manufacturing method of a nano-laminated film of the present invention, each supercycle step comprises the following steps:

S11: Repeating the first single-cycle step for several times to form a plurality of first metal oxide layers.

S12: Repeating the second single-cycle step for several times to form a plurality of second metal oxide layer on the plurality of first metal oxide layers, wherein one first metal oxide layer is formed in this first unit cycle step, and one second metal oxide layer is formed in this second unit cycle step.

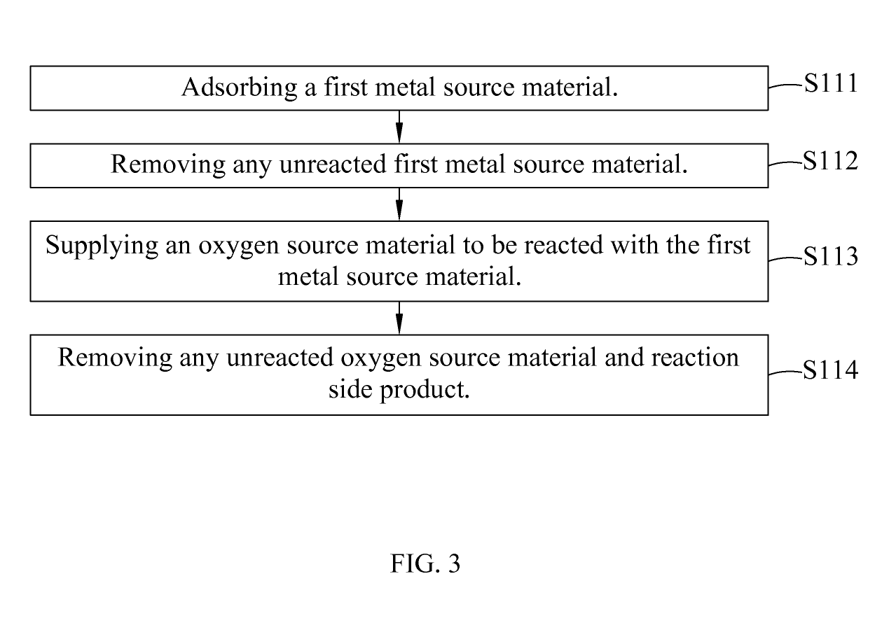

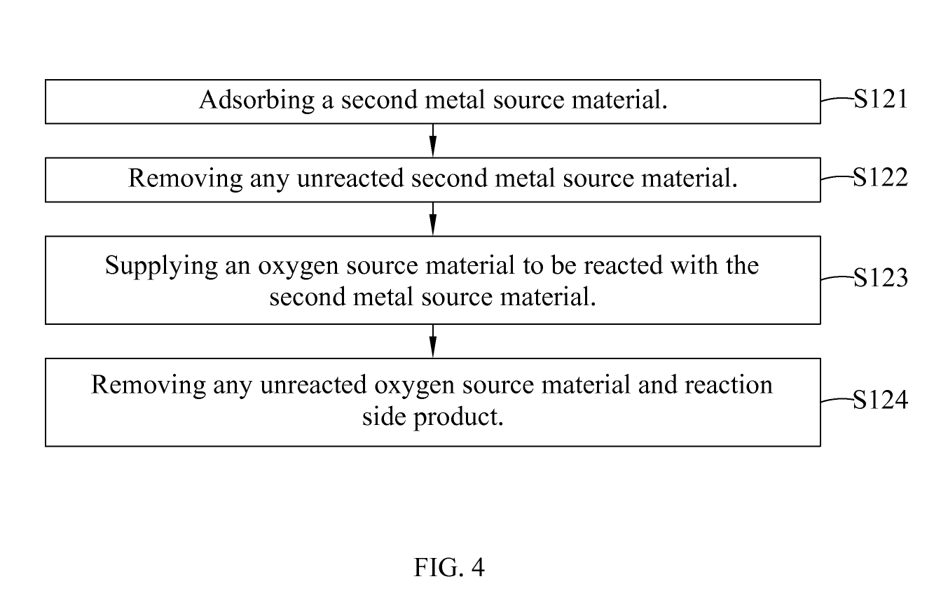

With reference to FIGS. 3 and 4 for schematic views of the first and second unit cycle steps of a manufacturing method of a nano-laminated film of the present invention respectively, the first unit cycle comprises the following steps:

S111: Adsorbing a first metal source material.

S112: Removing any unreacted first metal source material.

S113: Supplying an oxygen source material to be reacted with the first metal source material.

S114: Removing any unreacted oxygen source material and reaction side product.

The second unit cycle of the present invention comprises the following steps:

S121: Adsorbing a second metal source material.

S122: Removing any unreacted second metal source material.

S123: Supplying an oxygen source material to be reacted with the second metal source material.

S124: Removing any unreacted oxygen source material and reaction side product.

If the first metal oxide layer 111 and the second metal oxide layer 112 are zinc oxide (ZnO) layers, aluminum oxide layers, indium oxide layers, titanium oxide layers, manganese oxide layers, germanium oxide layers or germanium indium oxide layers, the first metal source and the second metal source can be an organic metal source of a metal including zinc, aluminum, indium, titanium, manganese, germanium or germanium-indium. The oxygen source material can be O₃, H₂O or O₂ plasma used for oxidizing and adsorbing the first metal source or second metal source onto a substrate surface to form a first metal oxide layer or a second metal oxide layer. In the steps S112, S114, S122 and S124, nitrogen gas or an inert gas is supplied into a reaction chamber for the atomic layer deposition to remove any non-reacted first metal source material, second metal source material, oxygen source material and reaction side products.

The manufacturing method of a nano-laminated film in accordance with the first preferred embodiment of the present invention is described below. In the first preferred embodiment, the atomic layer deposition (ALD) technology is used to manufacture the nano-laminated film of the present invention, wherein parameters of the manufacturing process are controlled to form a high density spinel phase.

In the first preferred embodiment, zinc oxide (ZnO) is used for the first metal oxide layer, and aluminum oxide (Al₂O₃) is used for the second metal oxide layer. The first metal source material is trimethyl aluminum (TMA), and the second metal source material is diethylzinc (DEZ). If each nanocomposite layer comprised of the aluminum oxide (Al₂O₃) layers and the zinc oxide (ZnO) layers contains N layers of zinc oxide layers and O layers of aluminum oxide layers, and a nano-laminated film contains M layers of the nanocomposite layer having the same structure, wherein M, N and O are positive integers greater than zero.

In the first preferred embodiment, the first unit cycle is used to form a single zinc oxide layer, and the second unit cycle is used to form a single aluminum oxide layer in a reaction chamber, and the pressure of the reaction chamber is maintained within a range from 2 Torrs to 14 Torrs. In the first and second unit cycles of the first preferred embodiment, (1) the first metal source which is trimethyl aluminum (TMA) and the second metal source which is diethylzinc (DEZ) is passed into the reaction chamber for a fixed time of 0.2 second; (2) nitrogen gas is used for removing any non-adsorbed first metal source (TMA) and second metal source (DEZ), and any non-reacted oxygen source material and reaction side products, wherein the nitrogen is supplied for a fixed time of 5 seconds; and (3) In the step of supplying the oxygen source material, H₂O is passed into the reaction chamber for 0.2 second to serve as an oxygen source.

After the fixed first unit cycle and second unit cycle are changed in the experiment, the relation between the percentage of the number of aluminum oxide layers in each nanocomposite layer and the surface roughness of the nanocomposite layer is examined. In this test, each nanocomposite layer has N zinc oxide layers and O aluminum oxide layer, and the total of N and O is equal to 50.

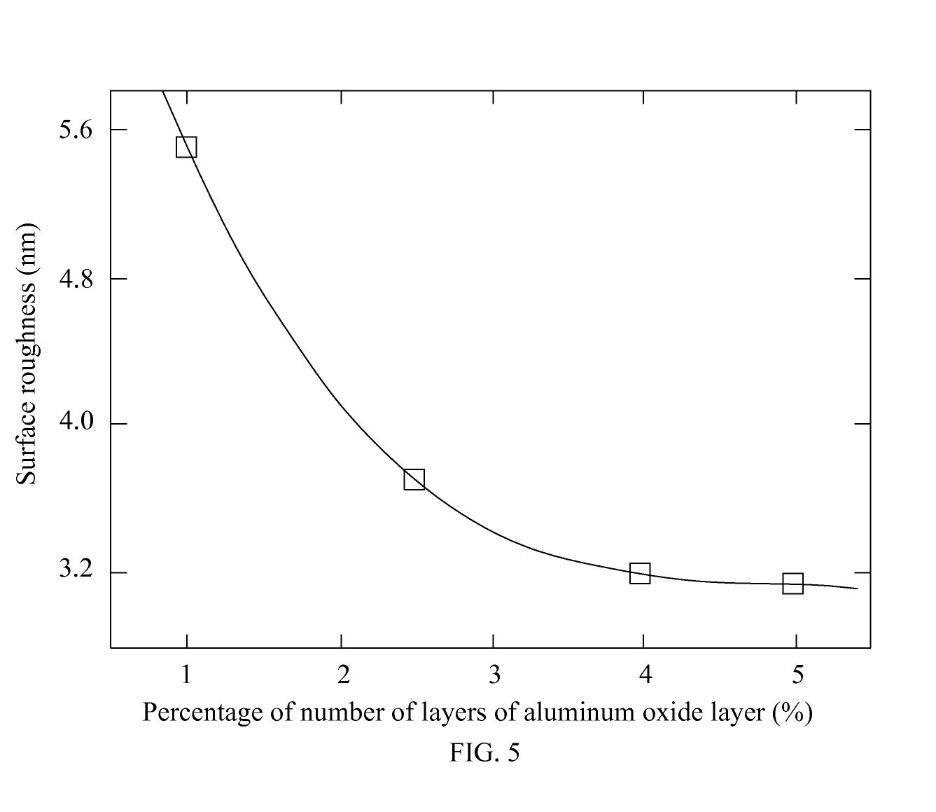

With reference to FIG. 5 for a graph of surface roughness of a nanocomposite layer versus percentage of number of aluminum oxide (Al₂O₃) layers in accordance with the present invention, test results of the surface roughness of the nanocompsite layer are obtained, when the substrate reaction temperature (Tsub) of each step in the first unit cycle and the second unit cycle of this testing is fixed to room temperature (RT), and N and (N+O) have the percentages of 1%, 2.5%, 4% and 5%.

FIG. 5 shows that the greater the percentage of the number of aluminum oxide layers, the smaller is the surface roughness of the nanocomposite layer. Therefore, the percentage of numbers of layers in the Al₂O₃ thin film can be controlled to improve the defective rate of the thin film and optimize the optical properties of the optoelectronic thin film. The ratio of 0 to (N+O) falls within a range from 2% to 5%, the obtained nanocomposite layer can have a flatter surface. The flat and smooth surface allows repeated laminations of the plurality of nanocomposite layers to form the nano-laminated film, and the product features a high density and a low surface light scattering property.

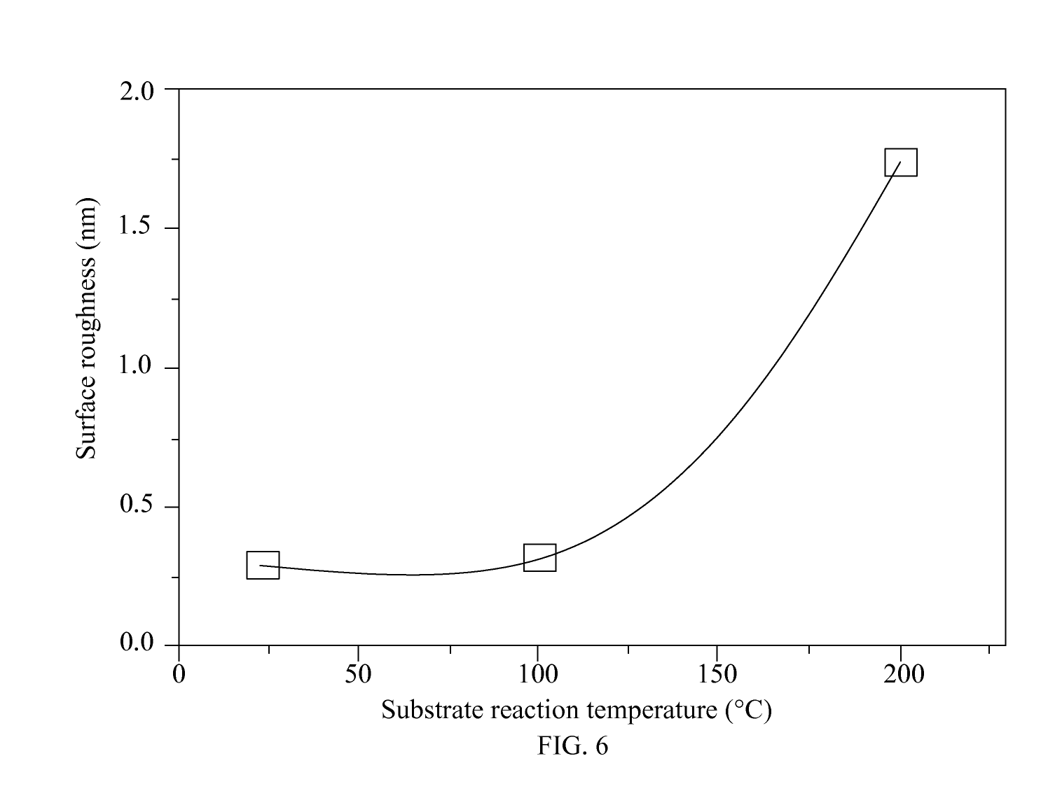

Therefore, if the percentage of numbers of layers pre-formed on the aluminum oxide layer is below 5%, the relation between the reaction temperature (Tsub) of the substrate and the surface roughness of each nanocomposite layer is examined. An atomic force microscope (AFM) is used to test the surface roughness. With reference to FIG. 6 for a graph of surface roughness of a nanocomposite layer of a nano-laminated film versus substrate reaction temperature in accordance with the present invention, the higher the reaction temperature of the substrate in the first unit cycle and second unit cycle, the greater is the surface roughness of the nanocomposite layer, but the surface roughness is still flatter than the nano thin film produced by a conventional manufacturing process performed at the same temperature.

An XRR test is taken to test the thin film density of a nano-laminated film containing five aluminum oxide layers formed at different substrate temperatures, the thin film density of 45 zinc oxide layers, and the thin film density at a contact interface of these aluminum oxide layers and these zinc oxide layers. The test results show that if the substrate reaction temperature falls within the range from 100° C. to 250° C., an average density at the contact interface of these aluminum oxide layers and these zinc oxide layers falls into a range between 5.5 g/cm³ and 7.2 g/cm³, and this density falls within the density interval of the aluminum-zinc oxide formed by aluminum oxide and zinc oxide and having the property of a spinel phase. The test results show that the thin film can be formed by the atomic deposition method, and a spinel phase interface layer can be formed at a contact interface between the first metal oxide layer and the second metal oxide layer by controlling the substrate reaction temperature according to the materials of the first metal oxide layer and the second metal oxide layer.

The aforementioned test shows that if a dense-integrity nanocomposite layer made of an aluminum oxide-zinc oxide with an aluminum zinc oxide (AZO) spinel interface is required, the substrate reaction temperature in the first unit cycle and the second unit cycle is controlled at a temperature from 100° C. to 250° C. , and the percentage of the number of aluminum oxide layers is controlled within a range of 2% to 5%. With the aforementioned conditions, the average thickness of a single zinc oxide layer formed in one first unit cycle falls within a range from 1.7 Å to 2 Å, and the average thickness of a single aluminum oxide layer formed in one second unit cycle falls within a range from 0.9 Å to 1.1 Å.

It shows that if the substrate reaction temperature in the first unit cycle and the second unit cycle is controlled within a range of 100° C. to 250° C., and the percentage of number of aluminum oxide layers is controlled within a range of 2% to 5%, an aluminum oxide (Al₂O₃)-zinc oxide (ZnO) nanocomposite layer can have an aluminum-zinc oxide (AZO) spinel phase formed between a plurality of aluminum oxide layers and a plurality of zinc oxide layers. And then, the relation between the thickness and the conductivity is examined.

In an organic light emitting diode (OLED) packaging application, a packaging material with the water vapor resisting function and a transparent conductive thin film are used as outer component package and inner components and as an upper electrode and a lower electrode in the OLED device to achieve the packaging and circuit layout.

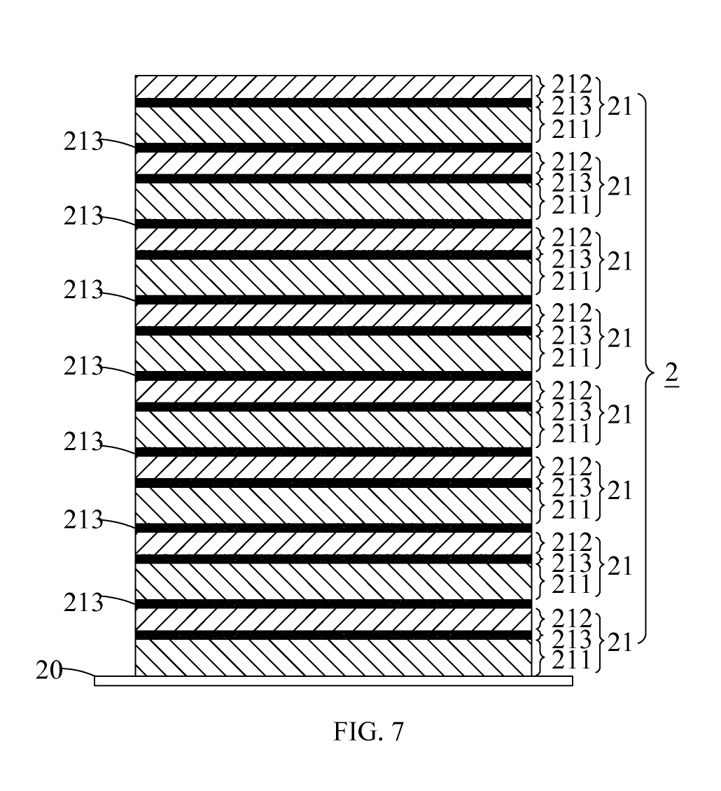

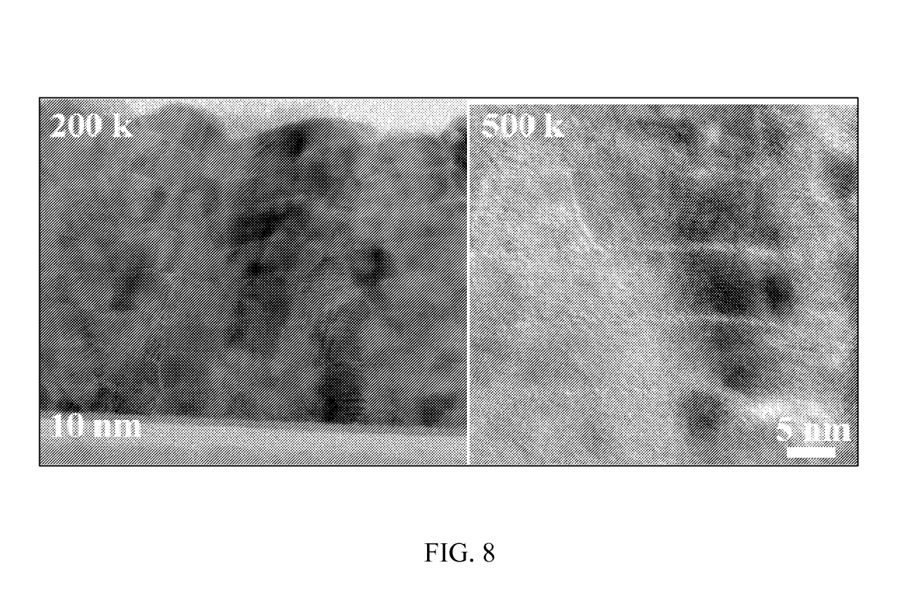

To apply the nano-laminated film of the present invention to the packaging and circuit layout of the OLED effectively, it is preferably to have a low resistivity (falling between 10⁻³ Ω-cm and 10⁻⁴ Ω-cm. Test results show that the same nanocomposite layer structure can be formed repeatedly for eight times, and the resistivity of the nano-laminated film can reach 6×10⁻⁴ Ω-cm. After a series of tests, the nano-laminated film 2 of the first preferred embodiment of the present invention preferably has 8 layers (M=8) of aluminum oxide -zinc oxide nanocomposite layers 21 laminated with each other on the substrate 20, and each of the aluminum oxide-zinc oxide nanocomposite layers comprises 45 layers (N=45) of zinc oxide (ZnO) layers 211, and five layers (O=5) of aluminum oxide (Al₂O₃) layers 212 formed on the 45 zinc oxide (ZnO) layers, and an aluminum-zinc oxide spinel phase 213 is formed at a contact interface of these zinc oxide (ZnO) layers 211 and these aluminum oxide (Al₂O₃) layers 212. With reference to FIG. 7 for a schematic view of a nano-laminated film 2 in accordance with the first preferred embodiment of the present invention and FIG. 8 for a transmission electronic microscope (TEM) photo of a nano-laminated film in accordance with the first preferred embodiment of the present invention, the thin film manufactured by the atomic deposition method is proven to have a flat and dense thin film structure.

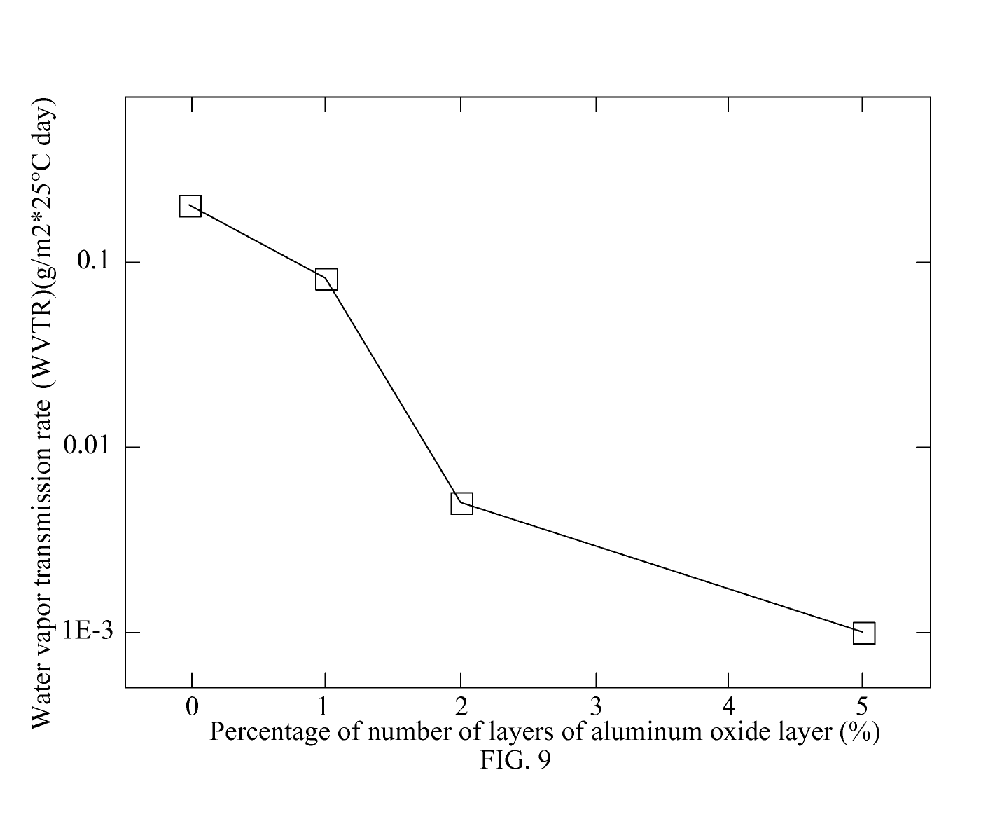

Based on the structure of the nano-laminated film in accordance with the first preferred embodiment of the present invention, the change of the water vapor blocking effect of the nano-laminated film is examined, provided that the aluminum oxide layer 212 has the percentage of numbers of layers from 0% to 5%. With reference to FIG. 9 for a graph of the water vapor blocking effect, the percentage of numbers of layers the aluminum oxide layer 212 of the first preferred embodiment varies from 0% to 5%. As the aluminum oxide layer 212 changes its percentage of numbers of layers from 0% to 5%, the water vapor blocking effect becomes increasing better. Particularly, when the aluminum oxide layer has a percentage of numbers of layers equal to 5%, the water vapor resistance reaches 0.001 g/m², which can comply with the industrial standard for packaging electronic devices. With the aforementioned manufacturing conditions, the number of aluminum oxide layers 212 can be changed or increased to improve the water vapor resisting effect.

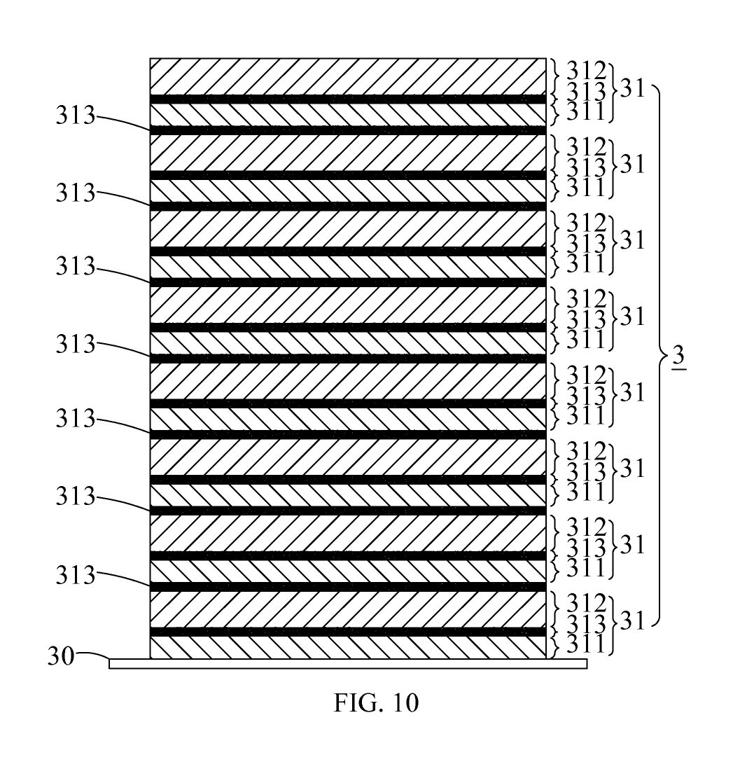

With reference to FIG. 10 for a schematic view of a nano-laminated film in accordance with a second preferred embodiment of the present invention, nano-laminated film 3, eight aluminum oxide -zinc oxide nanocomposite layers 31 are also laminated onto a substrate 30, and each the aluminum oxide-zinc oxide nanocomposite layer 31 comprises five aluminum oxide (Al₂O₃) layers 311, 45 zinc oxide (ZnO) layers 312 formed on the five aluminum oxide (Al₂O₃) layers 311, and an aluminum-zinc oxide spinel phase 313 formed at a contact interface of these aluminum oxide (Al₂O₃) layers 311 and these zinc oxide (ZnO) layers 312. The difference between the nano-laminated film 3 and the nano-laminated film 2 resides on that the arrangement order of the aluminum oxide layer 311 and the zinc oxide layer 312 in each nanocomposite layer 31 of each nano-laminated film 3 are switched, and the switched order does not affect the properties of the aluminum-zinc oxide spinel phase formed at the contact interface of the aluminum oxide layer and the zinc oxide layer, and the aluminum-zinc oxide layer with the spinel phase property profoundly affects the water vapor blocking effect. Each aluminum oxide layer and each zinc oxide layer are formed by the same method of the first preferred embodiment, and thus will not be described again.

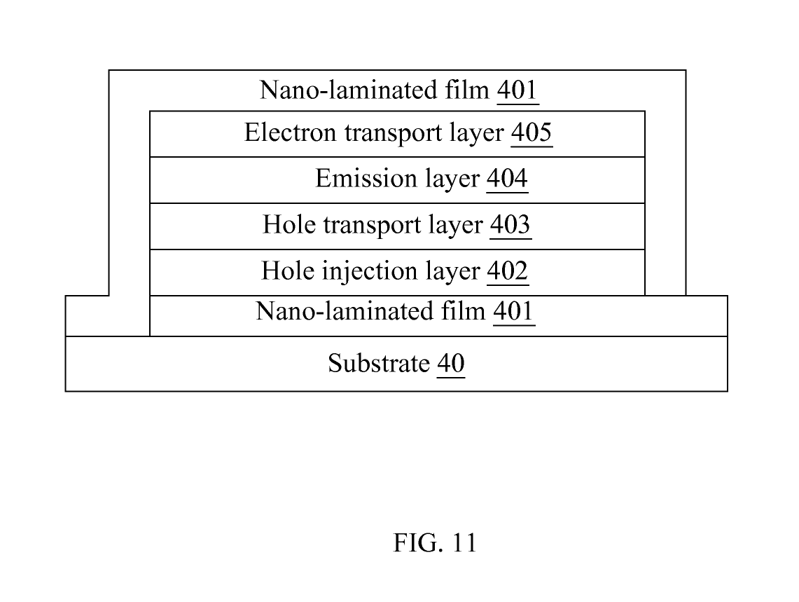

With reference to FIG. 11 for a schematic view of a nano-laminated film applied for packaging an OLED in accordance with a preferred embodiment of the present invention, the nano-laminated film 401 with a conductivity from 10⁻⁴ Ω-cm to 10⁻³ Ω-cm and a water vapor resisting property is used for packaging the thin film as well as serving as the upper electrode and the lower electrode of the OLED device.

Accordingly, the upper and lower electrodes covers the entire OLED device and achieves the intended purpose of the packaging, wherein, the OLED device comprises a hole injection layer 402, hole transport layer 403, emission layer 404, electron transport layer 405 and a nano-laminated film 401 as a packaging thin film which can serve as an upper and lower electrode.

The nano-laminated film of the present invention formed by using atomic layer deposition technology (ALD), by adjusting the various depository conditions such as the type of first metal oxide or second metal oxide, adjusting the substrate reaction temperature or reaction chamber pressure, or adjusting the percentage of numbers of layers of the first metal oxide layer or second oxide layer within each nanocomposite layer structure etc, can indeed optimize the roughness, density, thickness and other properties of the first metal oxide layer and second oxide layer that is formed. In order to promote the forming of a spinel phase in between the first metal oxide layer and the second metal oxide layer, such that the nano-laminated film will have the characteristics of a high density spinel phase, as well as excellent water vapor blocking effect. Wherein, the deposition conditions for the forming of spinel phase between different metal oxides are not the same.

What is claimed is:

1. A nano-laminated film with transparent conductive property and water-vapor resistance function, comprising:
a plurality of nanocomposite layers, disposed on a substrate, and each of the nanocomposite layers comprising:
a plurality of first metal oxide layers; and
a plurality of second metal oxide layers, formed on the first metal oxide layers;
wherein, the first metal oxide layers and the second metal oxide layers are formed by different materials, and a spinel phase is formed at a contact interface of the first metal oxide layers and the second metal oxide layers.

2. The nano-laminated film of claim 1, wherein the first metal oxide layer is one selected from a collection of a zinc oxide layer, a titanium aluminum oxide layer, an aluminum oxide layer, an indium oxide layer, a titanium oxide layer, a manganese oxide layer, a germanium oxide layer and a germanium indium oxide layer.

3. The nano-laminated film of claim 1, wherein the second metal oxide layer is one selected from a collection of a zinc oxide layer, a titanium aluminum oxide layer, an aluminum oxide layer, an indium oxide layer, a titanium oxide layer, a manganese oxide layer, a germanium oxide layer and a germanium indium oxide layer.

4. The nano-laminated film of claim 1, wherein if the first metal oxide layer or the second metal oxide layer is a zinc oxide layer, the zinc oxide layer has a thickness falling within a range from 1.7 Å to 2 Å.

5. The nano-laminated film of claim 4, wherein if the first metal oxide layer or the second metal oxide layer is an aluminum oxide layer, the aluminum oxide layer has a thickness falling within a range from 0.9 Å to 1.1 Å.

6. The nano-laminated film of claim 5, wherein each of the nanocomposite layers has a plurality of aluminum oxide layers and a plurality of zinc oxide layers in a ratio of 2:98 to 5:95.

7. The nano-laminated film of claim 6, wherein the plurality of nanocomposite layers has a total thickness, and if the total thickness is greater than 80 nm, the plurality of nanocomposite layers has a resistivity falling within a range from 10⁻³ to 10⁻⁴ Ω-cm, and a water vapor transmission rate below 0.001 g/m²day.

8. The nano-laminated film of claim 6, wherein the spinel phase has an average density falling within a range from 5.5 g/cm³ to 7.2 g/cm³.

9. The nano-laminated film of claim 1, wherein the substrate is a plastic substrate.

10. The nano-laminated film of claim 1, wherein the plurality of nanocomposite layers serves as an upper electrode or a lower electrode of an organic light emitting diode (OLED).

11. A manufacturing method of a nano-laminated film with a transparent conductive property and a water vapor blocking function, using an atomic deposition method for the manufacture, and comprising the steps of:
repeating a supercycle step to form a plurality of nanocomposite layers on a substrate, and the supercycle step comprising:
repeating a first unit cycle step to form a plurality of first metal oxide layers; and
repeating a second unit cycle step to form a plurality of second metal oxide layers;
wherein the first metal oxide layers and the second metal oxide layers are made of different materials, and the first unit cycle step and the second unit cycle step are performed in a reaction chamber, and a reaction pressure of the reaction chamber, a reaction temperature of the substrate, a percentage of numbers of the first metal oxide layers and the second metal oxide layers of each nanocomposite layer are controlled, and a spinel phase is formed at a contact interface of the first metal oxide layer and the second metal oxide layer.

12. The manufacturing method of a nano-laminated film as recited in claim 11, wherein the first metal oxide layer is one selected from a collection of a zinc oxide layer, a titanium aluminum oxide layer, an aluminum oxide layer, an indium oxide layer, a titanium oxide layer, a manganese oxide layer, a germanium oxide layer and a germanium indium oxide layer.

13. The manufacturing method of a nano-laminated film as recited in claim 11, wherein the second metal oxide layer is one selected from a collection of a zinc oxide layer, a titanium aluminum oxide layer, an aluminum oxide layer, an indium oxide layer, a titanium oxide layer, a manganese oxide layer, a germanium oxide layer and a germanium indium oxide layer.

14. The manufacturing method of a nano-laminated film as recited in claim 11, wherein if the first metal oxide layer or the second metal oxide layer is a zinc oxide layer, the zinc oxide layer has a thickness falling within a range from 1.7 Å to 2 Å.

15. The manufacturing method of a nano-laminated film as recited in claim 14, wherein if the first metal oxide layer or the second metal oxide layer is an aluminum oxide layer, the aluminum oxide layer has a thickness falling within a range from 0.9 Å to 1.1 Å.

16. The manufacturing method of a nano-laminated film as recited in claim 15, wherein the reaction pressure falls within a range from 2 Torrs to 14 Torrs, and the temperature of the substrate falls within a range from 100° C. to 250° C.

17. The manufacturing method of a nano-laminated film as recited in claim 15, wherein /the number of aluminum oxide layers and the number of zinc oxide layers in each of the nanocomposite layers are in a ratio falling within a range from 2:98 to 5:95.

18. The manufacturing method of a nano-laminated film as recited in claim 17, wherein the plurality of nanocomposite layers has a total thickness, and if the total thickness is greater than 80 nm, the plurality of nanocomposite layers has a resistivity falling within a range from 10⁻³Ω-cm to 10⁻⁴ Ω-cm, and a water vapor transmission rate below 0.001 g/m²day.

19. The manufacturing method of a nano-laminated film as recited in claim 11, wherein the substrate is a plastic substrate.

20. The manufacturing method of a nano-laminated film as recited in claim 11, wherein the plurality of nanocomposite layers serves as an upper electrode or a lower electrode of an organic light emitting diode (OLED).
